(19) United States
(12) Patent Application Publication
(10) Pub. No.: US 2014/0167284 A1
(43) Pub. Date: Jun. 19, 2014

(54) INTERCONNECT STRUCTURE AND FORMING METHOD THEREOF

(71) Applicant: Grace Semiconductor Manufacturing Corporation, Shanghai (CN)

(72) Inventor: Ernest Li, Shanghai (CN)

(73) Assignee: Grace Semiconductor Manufacturing Corporation, Shanghai (CN)

(21) Appl. No.: 14/036,953

(22) Filed: Sep. 25, 2013

(30) Foreign Application Priority Data
Dec. 19, 2012 (CN) 201210557309.1

(51) Int. Cl. H01L 21/768; H01L 23/522

(52) U.S. Cl. CPC H01L 21/76877; H01L 23/5226
USPC 257/774; 438/637

(57) ABSTRACT

An interconnect structure and a forming method thereof are provided. The method includes: providing a semiconductor substrate which has semiconductor devices formed therein; forming an interlayer dielectric layer on the semiconductor substrate; forming a conductive layer on the interlayer dielectric layer; forming a groove in the conductive layer and the interlayer dielectric layer, the groove having a depth smaller than a sum of a thickness of the conductive layer and a thickness of the interlayer dielectric layer and having a depth-to-width ratio greater than 0.8; and depositing an intermetallic dielectric layer to cover the conductive layer and fill the groove, and forming an air gap in the intermetallic dielectric layer in the groove. The depth-to-width ratio of the groove and a size of the air gap are increased. Therefore, parasitic capacitance between the adjacent interconnects is reduced, and the performance of the semiconductor devices is improved.

### CROSS-REFERENCE TO RELATED APPLICATIONS

The present application claims priority to Chinese patent application No. 201210557309.1, filed on Dec. 19, 2012, and entitled “INTERCONNECT STRUCTURE AND FORMING METHOD THEREOF”, and the entire disclosure of which is incorporated herein by reference.

### FIELD OF THE DISCLOSURE

The present disclosure generally relates to semiconductor technology, and more particularly, to an interconnect structure and a forming method thereof.

### BACKGROUND OF THE DISCLOSURE

Conventional methods for forming a metal interconnect structure may include:

referring to FIG. 1, providing a semiconductor substrate 100, forming an dielectric layer 101 on the semiconductor substrate 100, and forming a metal layer 102 on the dielectric layer 101;

referring to FIG. 2, forming a patterned photoresist layer on the metal layer 102 and etching the metal layer 102 by taking the patterned photoresist layer as a mask to form a groove 103, the metal layer 102 on two sides of the groove 103 forming metal interconnects; and

referring to FIG. 3, depositing an intermetallic dielectric layer 104 which fills the groove 103 and covers the metal layer 102.

However, when technology node is developed to less than 90 nm, the distance between adjacent metal interconnects becomes shorter and parasitic capacitance generated therebetween becomes greater. The parasitic capacitance may not only affect a running speed of a chip but also reduce the reliability of devices on the chip. To alleviate the problem, materials with a high dielectric constant, such as silicon dioxide are replaced with low-K dielectric materials to form an interlayer dielectric layer and an intermetallic dielectric layer in semiconductor processes, which may reduce parasitic capacitance between adjacent metal interconnects. When technology node is developed to less than 32 nm, low-K dielectric materials may not have a good performance on reducing parasitic capacitance. Besides, even in processes with technology node of more than 90 nm, the conventional method of filling a groove between adjacent metal interconnects with an intermetallic dielectric layer, such as some radio frequency integrated circuits, cannot meet the technique requirement of minimizing parasitic capacitance between the adjacent metal interconnects.

To obtain more relative information of methods for forming a metal interconnect structure, please refer to US patent publication No. US2011/0018091A1.

### SUMMARY

In conventional solutions, parasitic capacitance between adjacent metal interconnects is great.

In an embodiment, a method for forming an interconnect structure may be provided, including:

providing a semiconductor substrate which has semiconductor devices formed therein;

forming an interlayer dielectric layer on the semiconductor substrate;

forming a conductive layer on the interlayer dielectric layer;

forming a groove in the conductive layer and the interlayer dielectric layer, the groove having a depth smaller than a sum of a thickness of the conductive layer and a thickness of the interlayer dielectric layer and having a depth-to-width ratio greater than 0.8; and

depositing an intermetallic dielectric layer to cover the conductive layer and fill the groove, and forming an air gap in the intermetallic dielectric layer in the groove.

Optionally, the interlayer dielectric layer and the intermetallic dielectric layer may include a low-K dielectric material or an ultra-low-K dielectric material.

Optionally, the interlayer dielectric layer may include silicon dioxide.

Optionally, the intermetallic dielectric layer may be formed by a plasma enhanced chemical vapor deposition (PECVD) process.

Optionally, the intermetallic dielectric layer may include silicon dioxide.

Optionally, the conductive layer may include aluminium or tungsten.

Optionally, the groove may be formed by a photoetching process or an etching process.

In an embodiment, an interconnect structure may be provided, including:

a semiconductor substrate which has semiconductor devices formed therein;

an interlayer dielectric layer formed on the semiconductor substrate;

interconnects formed on the interlayer dielectric layer;

grooves between the adjacent interconnects, the grooves having a depth smaller than a sum of a thickness of the interconnects and a thickness of the interlayer dielectric layer and having a depth-to-width ratio greater than 0.8; and

an intermetallic dielectric layer which covers the interconnects and fills the grooves, where air gaps are formed in the intermetallic dielectric layer in the grooves.

Optionally, the interlayer dielectric layer and the intermetallic dielectric layer may include a low-K dielectric material or an ultra-low-K dielectric material.

Optionally, the interlayer dielectric layer may include silicon dioxide.

Optionally, the intermetallic dielectric layer may include silicon dioxide.

Optionally, the interconnects may include aluminium or tungsten.

Compared with the conventional solutions, the present disclosure may have following advantages.

In the present disclosure, grooves are formed in the conductive layer and the interlayer dielectric layer. A depth of the grooves is smaller than a sum of the thickness of interconnects and the thickness of an interlayer dielectric layer, i.e., the depth including the thickness of a conductive layer and the thickness of a portion of the interlayer dielectric layer, which increases the depth of the grooves and the depth-to-width ratio of the grooves between the adjacent interconnects. Therefore, while positing an intermetallic dielectric layer, air gaps may be more easily formed in the intermetallic dielectric layer in the grooves. More importantly, a size of the air gaps to be formed may be increased. Air gaps between the adjacent interconnects with a larger size may bring a smaller dielectric constant of the intermetallic dielectric layer between the adjacent interconnects and smaller parasitic capacitance between the adjacent interconnects, which reduces RC delay among semiconductor devices and power consumption of driving the interconnects, and improves the performance of the whole semiconductor devices. More particularly, in a radio frequency integrated circuit, coupling between adjacent interconnects may be reduced obviously.

### BRIEF DESCRIPTION OF THE DRAWINGS

FIGS. 1 to 3 schematically illustrate sectional views of intermediate structures of a conventional method for forming an interconnect structure with air gaps;

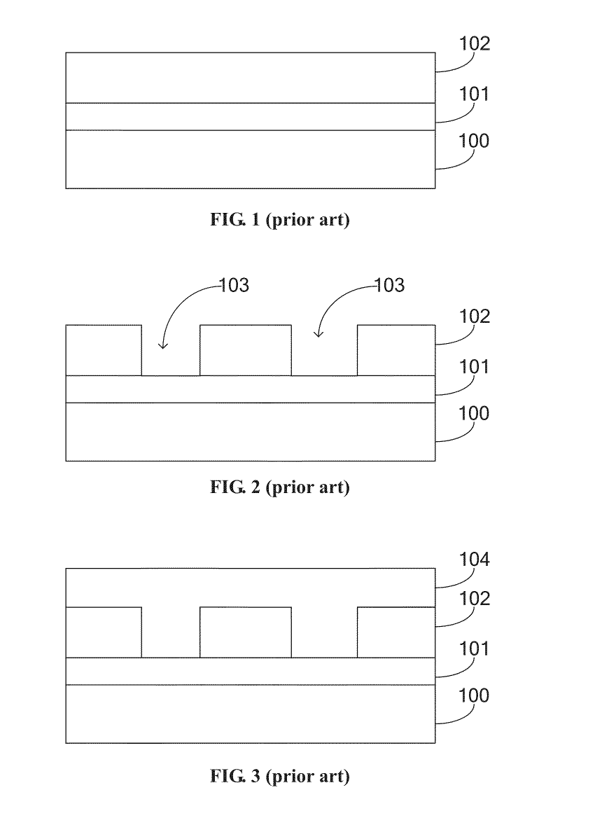

FIG. 4 schematically illustrates a sectional view of a conventional interconnect structure;

FIG. 5 schematically illustrates a flow chart of a method for forming an interconnect structure with air gaps according to one embodiment of the present disclosure; and

FIGS. 6 to 8 schematically illustrate sectional views of intermediate structures of a method for forming an interconnect structure with air gaps according to one embodiment of the present disclosure.

### DETAILED DESCRIPTION OF THE DISCLOSURE

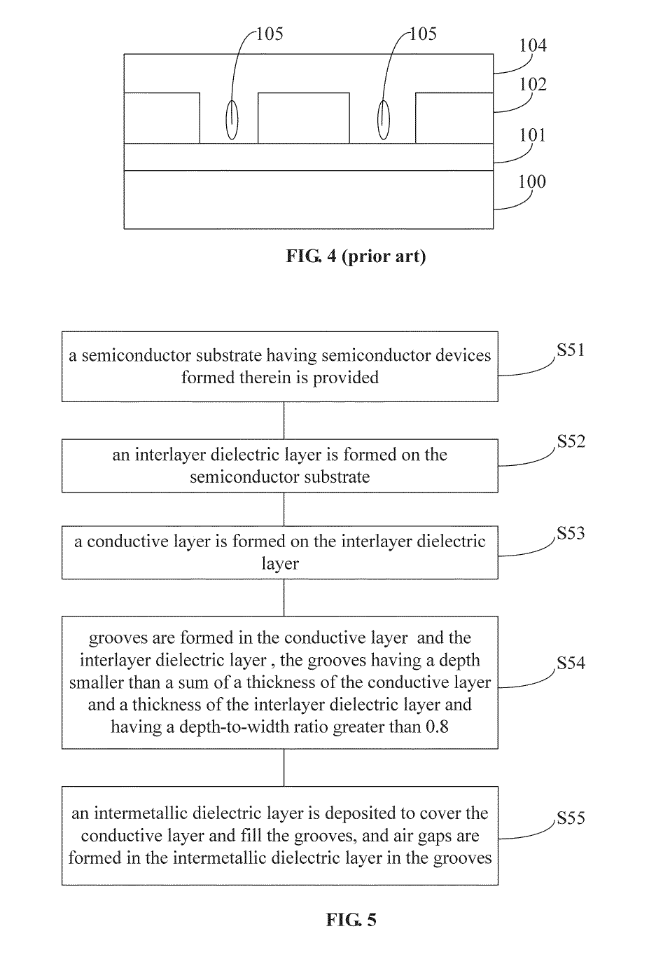

The inventors found that, referring to FIG. 4, when the distance between adjacent metal interconnects becomes shorter, air gaps 105 may be formed in an intermetallic dielectric layer 104 between the adjacent metal interconnects. The air gaps 105 may not increase parasitic capacitance between the adjacent metal interconnects and may reduce the parasitic capacitance. Therefore, forming air gaps between adjacent metal interconnects may effectively reduce parasitic capacitance between the metal interconnects.

The inventors have studied how to form air gaps in an intermetallic dielectric layer between adjacent metal interconnects and even how to form air gaps having a relatively large size.

A new method for forming an interconnect structure with air gaps is provided in the present disclosure.

In order to clarify the objects, characteristics and advantages of the disclosure, embodiments of present disclosure will be described in detail in conjunction with accompanying drawings. For convenience, elements in the drawings are not necessarily drawn to scale and the drawings as examples are not meant to limit the present disclosure. In practice, three-dimensional sizes including length, width and depth should be considered.

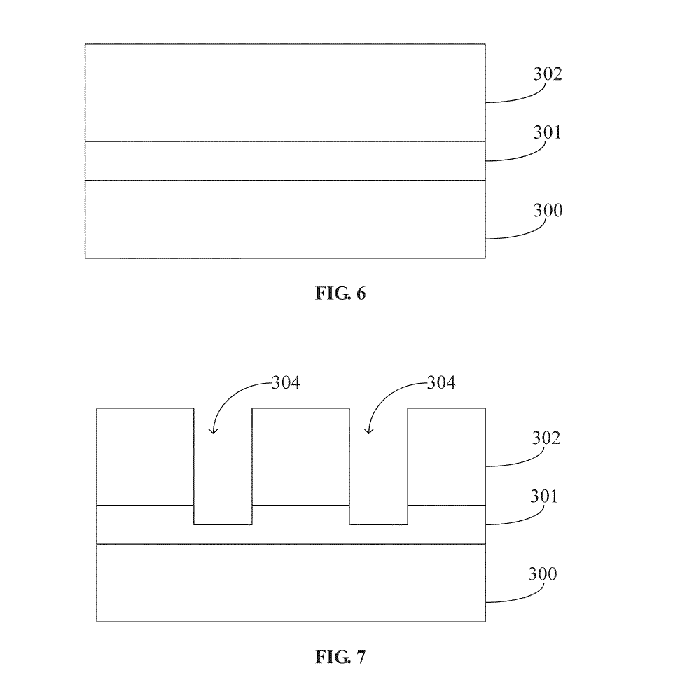

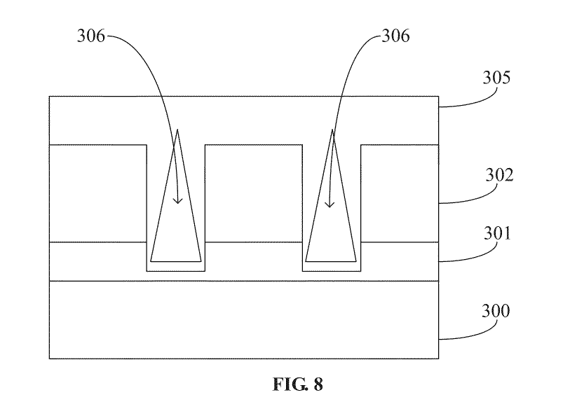

Referring to FIGS. 5 and 6, step S51 is performed. In S51, a semiconductor substrate 300 having semiconductor devices formed therein is provided.

In some embodiments, the semiconductor substrate 300 may include monocrystalline silicon, monocrystalline germanium, silicon-germanium, silicon carbide, silicon-on-insulator, germanium-on-insulator or other materials, such as group III-V compounds, for example gallium arsenide. In some embodiments, the semiconductor substrate 300 may have semiconductor devices formed therein, such as N-Mental-Oxide-Semiconductor (NMOS) transistor, P-Mental-Oxide-Semiconductor (PMOS) transistor, diode, capacitor or inductor.

Referring to FIGS. 5 and 6, step S52 is performed. In S52, an interlayer dielectric layer 301 is formed on the semiconductor substrate 300.

In some embodiments, the interlayer dielectric layer 301 may be adapted to insulate a conductive layer formed in subsequent processes and the semiconductor devices. In some embodiments, the interlayer dielectric layer 301 may have a single-layer structure or a laminated construction. The interlayer dielectric layer 301 may include silicon dioxide, a low-K dielectric material or an ultra-low-K dielectric material, such as one or more of carbon-doped dielectric material, carbon-doped organosilicon glass, carbon-doped silicon dioxide, fluorosilicone glass and silicon oxycarbide. In some embodiments, the interlayer dielectric layer 301 may be formed by a Chemical Vapor Deposition (CVD) process or a thermal oxidation growing process.

Still referring to FIGS. 5 and 6, step S53 is performed. In S53, a conductive layer 302 is formed on the interlayer dielectric layer 301. The conductive layer 302 is adapted to form interconnects.

In some embodiments, the conductive layer 302 may include a metal layer, namely, the conductive layer 302 may be a metal layer. When the conductive layer 302 is a metal layer, the metal layer may include aluminium or tungsten. In some embodiments, the metal layer may include aluminium. Since aluminium has low resistivity and excellent anti-electromigration capability, metal interconnects made of aluminium may reduce resistance thereof effectively. More importantly, aluminum is easily etched to form grooves between the adjacent metal layers in subsequent processes. In some embodiments, the metal layer may be formed by a sputtering process, but the present disclosure is not limited thereto. In some embodiments, the metal layer may be formed by other processes which are well known in the art.

Referring to FIGS. 5 and 7, step S54 is performed. In S54, grooves 304 are formed in the conductive layer 302 and the interlayer dielectric layer 301, the grooves 304 having a depth smaller than a sum of a thickness of the conductive layer 302 and a thickness of the interlayer dielectric layer 301, i.e., the depth including the thickness of the conductive layer 302 and the thickness of a portion of the interlayer dielectric layer 301. That is, the interlayer dielectric layer 301 is not etched entirely. The grooves 304 may have a depth-to-width ratio greater than 0.8, which means air gaps are more easily formed in an intermetallic dielectric layer in the grooves in subsequent processes and the air gaps may have a relatively large size.

In some embodiments, the grooves 304 may be formed by a photoetching process and an etching process. Specifically, the grooves 304 may be formed by: forming a patterned photoresist layer on the conductive layer 302 which defines a position of the grooves 304; etching the conductive layer 302 and a portion of the interlayer dielectric layer 301 by taking the patterned photoresist layer as a mask, but not to expose the semiconductor substrate 300; removing the patterned photoresist layer to form grooves 304. In some embodiments, the conductive layer 302 and the interlayer dielectric layer 301 may be etched by a dry etching process, such as a plasma etching process.

Referring to FIGS. 5, 7 and 8, step S55 is performed. In S55, an intermetallic dielectric layer 305 is deposited to cover the conductive layer 302 and fill the grooves 304, and air gaps 306 are formed in the intermetallic dielectric layer 305 in the grooves 304. The size of the air gaps 306 may be relevant to the depth-to-width ratio of the grooves 304. The greater the depth-to-width ratio is, the more easily the air gaps 306 are formed in the intermetallic dielectric layer 305 and the larger the size of the formed air gaps 306 is. Compared to the conventional technologies, in the present disclosure, a portion of the interlayer dielectric layer 301 is etched to form the grooves 304. Thus, a height of the grooves 304 is increased by a height of the portion of the interlayer dielectric layer 301, namely, the height of the grooves 304 is increased obviously, which increases the depth-to-width ratio of the grooves 304 between the conductive layer 302 as interconnects. With a greater depth-to-width ratio, the size of the air gaps 306 formed in the intermetallic dielectric layer 305 in the grooves 304 may be increased while depositing the intermetallic dielectric layer 305, which may reduce the dielectric constant of the intermetallic dielectric layer 305 between the adjacent interconnects and further reduce parasitic capacitance between the adjacent interconnects. Therefore, RC delay between the semiconductor devices may be improved effectively and the performance of the semiconductor devices may be improved.

Referring to FIG. 8, in some embodiments, air gaps 306 may take the shape of a triangle, which is illustrated for view but not the practical shape of the air gaps 306. In practice, according to specific processes and implementation methods, the air gaps 306 may have other irregular shapes. No matter what shape the air gaps 306 have, forming a metal interconnect structure with air gaps according to the embodiments of the present disclosure is within the scope of the present disclosure.

In some embodiments, the intermetallic dielectric layer 305 may be made of silicon oxide, a low-K dielectric material or an ultra-low-K dielectric material. The intermetallic dielectric layer 305 made of a low-K dielectric material or an ultra-low-K dielectric material may reduce the dielectric constant and parasitic capacitance between adjacent interconnects. However, some low-K dielectric materials and ultra-low-K dielectric materials are very expensive and not widely used at present. In some embodiments, the intermetallic dielectric layer 305 made of silicon oxide may be applied in forming an interconnect structure, which may not only reduce the dielectric constant and parasitic capacitance between adjacent interconnects effectively but also reduce production cost considerably. In some embodiments, the intermetallic dielectric layer 305 may be formed by a chemical vapor deposition process, such as a plasma enhanced chemical vapor deposition process, or other depositing processes, which is well known in the art and not described in detail here.

In some embodiments, after depositing an intermetallic dielectric layer, the intermetallic dielectric layer may not be completely even and have ups and downs along with patterns on a surface of the substrate. In some embodiments, a Chemical Mechanical Polishing (CMP) process may be employed to planarize the surface of the semiconductor substrate, which is beneficial to subsequent manufacturing processes.

It should be noted that, the depth-to-width ratio of adjacent interconnects may not only relevant to the thickness of the interconnects but also relevant to the distance between the adjacent interconnects. Although the effect of the distance between adjacent interconnects on the depth-to-width ratio of the adjacent interconnects is not described here, the distance's effect on the depth-to-width ratio cannot be ignored. In practical applications, according to the distance between interconnects and the thickness of the interconnects, the thickness needs to be adjusted to reach a better depth-to-width ratio, which reduces parasitic capacitance between the interconnects. When a low-L dielectric material or an ultra-low-K dielectric material is not employed, the present disclosure may not only reduce parasitic capacitance between interconnects, but also reduce production cost. Furthermore, the method of the present disclosure may be applied to some particular processes, such as a radio frequency circuit, where parasitic capacitance between interconnects may be reduced considerably.

Referring to FIG. 8, in some embodiments, an interconnect structure is provided, including: a semiconductor substrate 300 having semiconductor devices formed therein; an interlayer dielectric layer 301 which is formed on the semiconductor substrate 300 and covers the semiconductor substrate 300; interconnects formed on the interlayer dielectric layer 301; grooves 304 between the adjacent interconnects, which are formed in a conductive layer 302 and the interlayer dielectric layer 301, have a depth smaller than a sum of a thickness of the interconnects and a thickness of the interlayer dielectric layer 301 and have a depth-to-width ratio greater than 0.8; and an intermetallic dielectric layer 305 which covers the interconnects and fills the grooves 304 having air gaps 306 formed therein. In some embodiments, the size of the air gaps 306 may be larger than that in the conventional technologies, which reduces the dielectric constant of the intermetallic dielectric layer 305 between the adjacent interconnects, reduces or even eliminates parasitic capacitance between the adjacent interconnects, and improves the performance of the semiconductor devices.

In some embodiments, the interlayer dielectric layer 301 may include silicon oxide, a low-K dielectric material or an ultra-low-K dielectric material.

In some embodiments, the intermetallic dielectric layer 305 may include silicon oxide, a low-K dielectric material or an ultra-low-K dielectric material.

In some embodiments, the conductive layer 302 may include a metal, that is, the conductive layer 302 may be a metal layer. In some embodiments, the metal may be aluminium or tungsten. The metal layer may act as metal interconnects and the interconnect structure may be a metal interconnect structure.

Although the present disclosure has been disclosed as above with reference to preferred embodiments thereof but will not be limited thereto. Those skilled in the art can modify and vary the embodiments without departing from the spirit and scope of the present disclosure. Accordingly, without departing from the scope of the present disclosure, whatever simple modification and equivalent variation belong to the protection range of the present disclosure.

What is claimed is:

1. A method for forming an interconnect structure, comprising:
providing a semiconductor substrate which has semiconductor devices formed therein;
forming an interlayer dielectric layer on the semiconductor substrate;
forming a conductive layer on the interlayer dielectric layer;
forming a groove in the conductive layer and the interlayer dielectric layer, the groove having a depth smaller than a sum of a thickness of the conductive layer and a thickness of the interlayer dielectric layer and having a depth-to-width ratio greater than 0.8; and
depositing an intermetallic dielectric layer to cover the conductive layer and fill the groove, and forming an air gap in the intermetallic dielectric layer in the groove.

2. The method according to claim 1, wherein the interlayer dielectric layer and the intermetallic dielectric layer comprise a low-K dielectric material or an ultra-low-K dielectric material.

3. The method according to claim 1, wherein the interlayer dielectric layer comprises silicon dioxide.

4. The method according to claim 1, wherein the intermetallic dielectric layer is formed by a plasma enhanced chemical vapor deposition process.

5. The method according to claim 1, wherein the intermetallic dielectric layer comprises silicon dioxide.

6. The method according to claim 1, wherein the conductive layer comprises aluminium or tungsten.

7. The method according to claim 1, wherein the groove is formed by a photoetching process or an etching process.

8. An interconnect structure, comprising:
a semiconductor substrate which has semiconductor devices formed therein;
an interlayer dielectric layer formed on the semiconductor substrate;
interconnects formed on the interlayer dielectric layer;
grooves between the adjacent interconnects, the grooves having a depth smaller than a sum of a thickness of the interconnects and a thickness of the interlayer dielectric layer and having a depth-to-width ratio greater than 0.8; and
an intermetallic dielectric layer which covers the interconnects and fills the grooves which have air gaps formed therein.

9. The interconnect structure according to claim 8, wherein the interlayer dielectric layer and the intermetallic dielectric layer comprise a low-K dielectric material or an ultra-low-K dielectric material.

10. The interconnect structure according to claim 8, wherein the interlayer dielectric layer comprises silicon dioxide.

11. The interconnect structure according to claim 8, wherein the intermetallic dielectric layer comprises silicon dioxide.

12. The interconnect structure according to claim 8, wherein the interconnects comprise aluminium or tungsten.
